(19) United States
(12) Patent Application Publication
(10) Pub. No.: US 2010/0331060 A1
(43) Pub. Date: Dec. 30, 2010

(54) CONNECTOR UNIT AND ELECTRONIC EQUIPMENT

(75) Inventor: Nobuhiro Yoshida, Tokyo (JP)

Correspondence Address: Ditthavong Mori & Steiner, P.C., 918 Prince Street, Alexandria, VA, 22314, US

(73) Assignee: Sumitomo Bakelite Co. Ltd, Tokyo (JP)

(21) Appl. No.: 12/918,819

(22) PCT Filed: Mar. 11, 2008
(86) PCT No.: PCT/JP2008/000532

§ 371 Date: Aug. 23, 2010

(51) Int. Cl. H04M 1/00; H01R 12/24; H05K 7/00; H05K 1/00; H05K 3/30

(52) U.S. Cl. 455/575.1; 439/77; 361/749; 174/254; 29/832

(57) ABSTRACT

A connector unit includes a flexible substrate 120 having a main connector 110, a first sub-connector 111 and a second sub-connector 112, which are installed in a surface thereof, having an elongated shape to provide an configuration that the main connector 110 is located in an end of one surface of the connector unit and the first sub-connector 111 and the second sub-connector 112 are located in the other end when the flexible substrate 120 is folded at multiple locations. Thus, a connector unit capable of easily providing a special structure, in which one end of each of two flexible substrates is connected to a single main connector, and the other ends thereof are connected to the first sub-connector and the second sub-connector, respectively, can be presented.

### TECHNICAL FIELD

The present invention relates to a connector unit configured of having a plurality of coupling connectors installed in a flexible substrate, and particularly relates to a connector unit utilized in electronic equipment having a first housing and a second housing, which are configured to be slidable.

Further, the present invention relates to electronic equipment, which is configured that each of a plurality of relatively slidable main housings contains a circuit board, and particularly relates to electronic equipment, in which circuit boards that are capable of relatively moving are coupled to each other via a connector unit composed of a flexible substrate.

### BACKGROUND ART

Currently, electronic equipment such as mobile phone terminals and the like include products including a first housing and a second housing having openable and closable configuration or slidable configuration for the purpose of improving portability. In electronic equipment of slidable configuration, for example, a first housing is slidably connected to a second housing with a sliding mechanism.

Further, a circuit board, which is referred to as a “main substrate” or the like, is installed in the first housing, and a circuit board, which is referred to as a “sub-substrate” or the like, is installed in the second housing. The main substrate is connected to the sub-substrate via a connector unit.

Such connector unit has, for example, a flexible substrate having elongated shape. A coupling connector referred to as “main connector” or the like is installed in one end of one surface of the flexible substrate, and another coupling connector referred to as a “sub-connector” or the like is installed in the other end.

In the electronic equipment as described above, the main connector of the connector unit is coupled to the main substrate of the first housing, and the sub-connector is coupled to the sub-substrate of the second housing. In the electronic equipment as described above, the connector units are arranged along a curved arc-like line from the inside of the first housing to the inside of the second housing.

Since the first housing and the second housing are configured to be slidable in the electronic equipment as described above, both of the portability and the operationality are achieved. Nevertheless, a cable transmission between the main substrate contained in the first housing and the sub-substrate contained in the second housing can be achieved via the connector unit.

Moreover, such connector unit is composed of from the flexible substrate. Thus, a slide movement of the first housing and the second housing can be achieved without an interference to the cable transmission among the connector unit, the main substrate and the sub-substrate, and the connector unit provides no obstruction to the slide movement of the first housing and the second housing.

In addition to above, various proposals for the electronic equipment having the above-described configurations are made (for example, see Patent Documents 1 to 4).

### [Patent Document 1]

Japanese Patent Laid-Open No. 2006-128,808

### [Patent Document 2]

Japanese Patent Laid-Open No. 2004-222,173

### [Patent Document 3]

Japanese Patent Laid-Open No. 2004-222,145

### [Patent Document 4]

Japanese Patent Laid-Open No. 2003-110,675

### DISCLOSURE OF THE INVENTION

### Problem to be Solved by the Invention

Currently, multiple-functioning of the electronic equipment as described above is progressed, and for example, a product having a first sub-substrate and a second sub-substrate installed in a second housing in a parallel arrangement is produced. In this case, for example, it is configured that a main substrate is coupled to the first sub-substrate via a first connector unit, and the main substrate is also coupled to the second sub-substrate via a second connector unit.

However, this leads to increased number of components in electronic equipment, causing reduced productivity. Moreover, this also leads to a configuration of installing two coupling connectors in the main substrate, which provide reduced effective dimensional area of the main substrate due to the presence of the coupling connector.

In order to prevent this, it is assumed that the first connector unit for coupling the main substrate with the first sub-substrate and the second connector unit for coupling the main substrate with the second sub-substrate are integrated to a single unit.

In such case, a larger scale main connector coupled to the main substrate, a first sub-connector coupled to the first sub-substrate, a second sub-connector coupled to the second sub-substrate, a first elongated section composed of a flexible substrate for connecting the main substrate with the first sub-substrate, and a second elongated section composed of a flexible substrate for connecting the main substrate with the second sub-substrate, are prepared.

Next, an end of the first elongated section and an end of the second elongated section may be coupled to the main connector, and the first sub-connector may be coupled to the other end of the first elongated section, and the second sub-connector is coupled to the other end of the second elongated section.

However, this configuration requires that the first elongated section and the second elongated section are coupled to the single main connector with an overlapped configuration. In such case, the workability is poor since it is three-dimensionally configured, and thus the mechanization for the work is difficult.

In addition, when the main substrate is to be coupled to the first sub-substrate and the second sub-substrate with the connector unit having the structure as described above, the first elongated section and the second elongated section are stacked in a curved condition.

However, when slide movements of the first housing and the second housing in such structures are occurred, an interference may be generated in the first elongated section and the second elongated section. In such case, a disconnection may be generated in the first elongated section and the second elongated section, and/or the main connector, the first sub-connector or the second sub-connector may be fallen-off from the main substrate, the first sub-substrate or the second sub-substrate, causing malfunctions.

The present invention is made in view of the above-described problems, and is to provide a connector unit configured for easily manufacturing a structural unit, in which an end of a first elongated section and a second elongated section composed of flexible substrates is coupled to a single main connector and a first sub-connector and second sub-connector are installed to the other end thereof respectively.

Further, the present invention is made in view of the above-described problems, and is to provide electronic equipment configured for preventing an interference between the first elongated section and the second elongated section of the connector unit when a slide movement of the first housing and the second housing is occurred.

### Means for Solving Problem

A connector unit of the present invention is a connector unit configured to have a plurality of coupling connectors installed in a flexible substrate, comprising: a main connector, which is included in the coupling connectors; a first sub-connector, which is included in the coupling connectors and has a smaller dimension than the main connector; a second sub-connector, which is included in the coupling connectors and has a smaller dimension than the main connector; and a flexible substrate having the main connector, the first sub-connector and the second sub-connector, which are installed in one surface of the flexible substrate, wherein the flexible substrate having an elongated shape to provide an configuration that the main connector is located in an end of one surface of the connector unit and the first sub-connector and the second sub-connector are located in the other end when the flexible substrate is folded at multiple locations.

Therefore, in the connector unit of the present invention, the structure, in which one end of each of two flexible substrates is connected to a single main connector, and the other ends thereof are connected to the first sub-connector and the second sub-connector, respectively, is formed of a single flexible substrate, which includes the main connector, the first sub-connector, and the second sub-connector installed in one surface thereof.

Electronic equipment according to the present invention is configured to have a plurality of circuit boards coupled to via a connector unit, comprising: the connector unit of the present invention; a main substrate, included in the circuit boards and coupled with a main connector of the connector unit; a first sub-substrate, included in the circuit boards and coupled with a first sub-connector of the connector unit; and a second sub-substrate, included in the circuit boards and coupled with a second sub-connector of the connector unit.

A first flexible substrate of the present invention is a flexible substrate of one of the connector units of the present invention, comprising: a main installation section having an upper surface allowing therein installing of the main connector; a first elongated section abutted with a rear side of the main installation section; a first installation section abutted with a rear side of the first elongated section and having an upper surface allowing therein installing of the first sub-connector; a first connecting section abutted with a front side of the main installation section; a second connecting section abutted with one of right side and left side of the first connecting section; a second elongated section abutted with a rear side of the second connecting section; and a second installation section abutted with a rear side of the second connecting section and having an upper surface allowing therein installing of the second sub-connector.

A second flexible substrate of the present invention is a flexible substrate of the other of the connector units of the present invention, comprising: a main installation section having an upper surface allowing therein installing of the main connector; a first elongated section abutted with a rear side of the main installation section; a first installation section abutted with a rear side of the first elongated section and having an upper surface allowing therein installing of the first sub-connector; a second elongated section abutted with a front side of the main installation section; and a second installation section abutted with a front side of the second elongated section and having an upper surface allowing therein installing of the second sub-connector.

A first manufacturing process of the present invention is a process for manufacturing one connector unit of the present invention, including: forming the flexible substrate, the flexible substrate comprising: the main installation section having an upper surface allowing therein installing of the main connector; the first elongated section abutted with the rear side of the main installation section; the first installation section abutted with the rear side of the first elongated section and having an upper surface allowing therein installing of the first sub-connector; the first connecting section abutted with the front side of the main installation section; the second connecting section abutted with one of right side and left side of the first connecting section; the second elongated section abutted with the rear side of the second connecting section; and a second installation section abutted with the rear side of the second connecting section and having an upper surface allowing therein installing of the second sub-connector; installing the main connector in the upper surface of the main installation section; installing the first sub-connector in the upper surface of the first installation section; installing the second sub-connector in the upper surface of the second installation section; making a mountain fold at the boundary of the main installation section and the first connecting section; making a mountain fold at the boundary of the main installation section and the first elongated section; making a valley fold at the boundary of the first connecting section and the second elongated section; and making a mountain fold at the boundary of the first elongated section and the first installation section.

A second manufacturing process of the present invention is a process for manufacturing the other connector unit of the present invention, including: forming the flexible substrate, the flexible substrate comprising: the main installation section having an upper surface allowing therein installing of the main connector; a first elongated section abutted with a rear side of the main installation section; a first installation section abutted with a rear side of the first elongated section and having an upper surface allowing therein installing of the first sub-connector; a second elongated section abutted with a front side of the main installation section; and a second installation section abutted with a front side of the second elongated section and having an upper surface allowing therein installing of the second sub-connector, installing the main connector in the upper surface of the main installation section; installing the first sub-connector in the upper surface of the first installation section; installing the second sub-connector in the upper surface of the second installation section; making a mountain fold at the boundary of the main installation section and the first elongated section; and making a mountain fold at the boundary of the first elongated section and the first installation section.

Since the structure, in which one end of each of two flexible substrates is connected to a single main connector, and the other ends thereof are connected to the first sub-connector and the second sub-connector, respectively, is formed of a single flexible substrate, which includes the main connector, the first sub-connector, and the second sub-connector installed in one surface thereof in the connector unit of the present invention, a configuration, which is special and yet easily manufacturable, can be provided.

Electronic equipment of the present invention, is electronic equipment, configured to have relatively slidable plurality of main housings, each of which contains a circuit board housed therein, comprising: a first housing, included in the main housings; a second housing, included in the main housings; a sliding mechanism, relatively slidably supporting the first housing and the second housing; a main substrate serving as the circuit board housed in the first housing; a first sub-substrate serving as the circuit board housed in the second housing; a second sub-substrate serving as the circuit board housed in the second housing in parallel with the first sub-substrate; and a connector unit, connecting the main substrate with the first sub-substrate and the second sub-substrate, wherein the connector unit comprises: a main connector serving as a coupling connector coupled to the main substrate; a first sub-connector serving as a coupling connector coupled to the first sub-substrate; a second sub-connector serving as a coupling connector coupled to the second sub-substrate; a first elongated section composed of a flexible substrate and coupling the main connector with the first sub-connector; and a second elongated section composed of a flexible substrate and coupling the main connector with the second sub-connector; wherein the main substrate is coupled with the first sub-substrate via the first elongated section having a curved feature, wherein the main substrate is coupled with the second sub-substrate via the second elongated section having a curved feature to be overlapped over the first elongated section, wherein positions of the main connector, the first sub-connector and the second sub-connector and an overall length of the first elongated section and the second elongated section are defined, so that curved sections of the first elongated section and the second elongated section maintain a predetermined distance therebetween, even when a slide movement of the first housing and the second housing is made.

Therefore, curved sections of the first elongated section and the second elongated section maintain a predetermined distance therebetween, when a slide movement of the first housing and the second housing is occurred. Therefore, a slide movement of the first housing and the second housing causes no interference of the first elongated section and the second elongated section.

Since the electronic equipment of the present invention is configured that the curved sections of the first elongated section and the second elongated section maintain a predetermined distance therebetween when a slide movement of the first housing and the second housing is occurred, so that a slide movement of the first housing and the second housing causes no interference of the first elongated section and the second elongated section, a disconnection in the first elongated section and the second elongated section, and/or a falling-off of the main connector, the first sub-connector or the second sub-connector from the main substrate, the first sub-substrate or the second sub-substrate can be prevented.

While the determinations are made in reference to defined directions of front and rear, right and left, and top and bottom in the present invention, this definition is made for the purpose of a convenience in providing simple description for the relative relation of components of the present invention, and thus, it is not intended to limit any directions for the manufacture or the use in case conducting the present invention.

In addition, while each of a plurality of operations in the manufacturing processes of the present invention are described in a certain order, it is not intended to limit the order for implementing the plurality of operations by the described order. Thus, when the manufacturing process of the present invention is conducted, the order of the plurality of operations may be changed unless the change is harmful in the nature of the process.

For example, three operations for installing the main connector, the first sub-connector and the second sub-connector may be, of course, conducted in no particular order. In addition, the operations for folding various sections of the flexible substrate may be conducted in no particular order, provided that these provide a completion shape.

Further, the main connector and the others may be installed after the flexible substrates having different shapes, or alternatively, the main connector and the others may be installed to a sheet that composes the flexible substrates, and then the sheet may be cut to form the flexible substrates having different shapes.

### BRIEF DESCRIPTION OF THE DRAWINGS

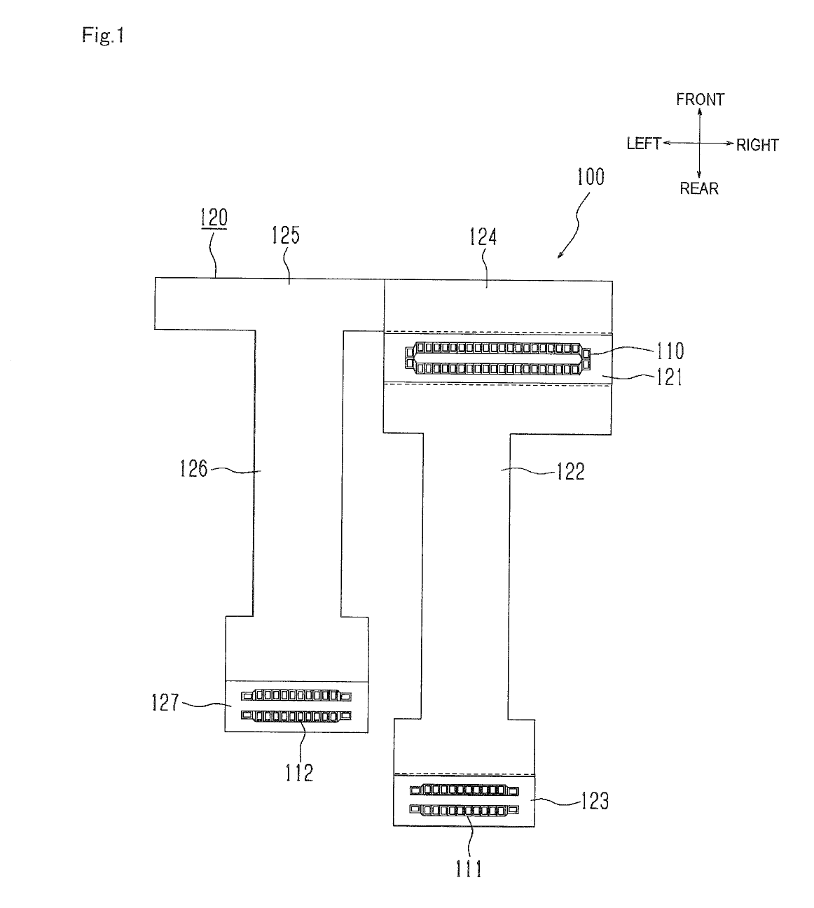

The above and other objects, advantages and features of the present invention will be more apparent from the following description of certain preferred embodiments taken in conjunction with the accompanying drawings.

[FIG. 1]

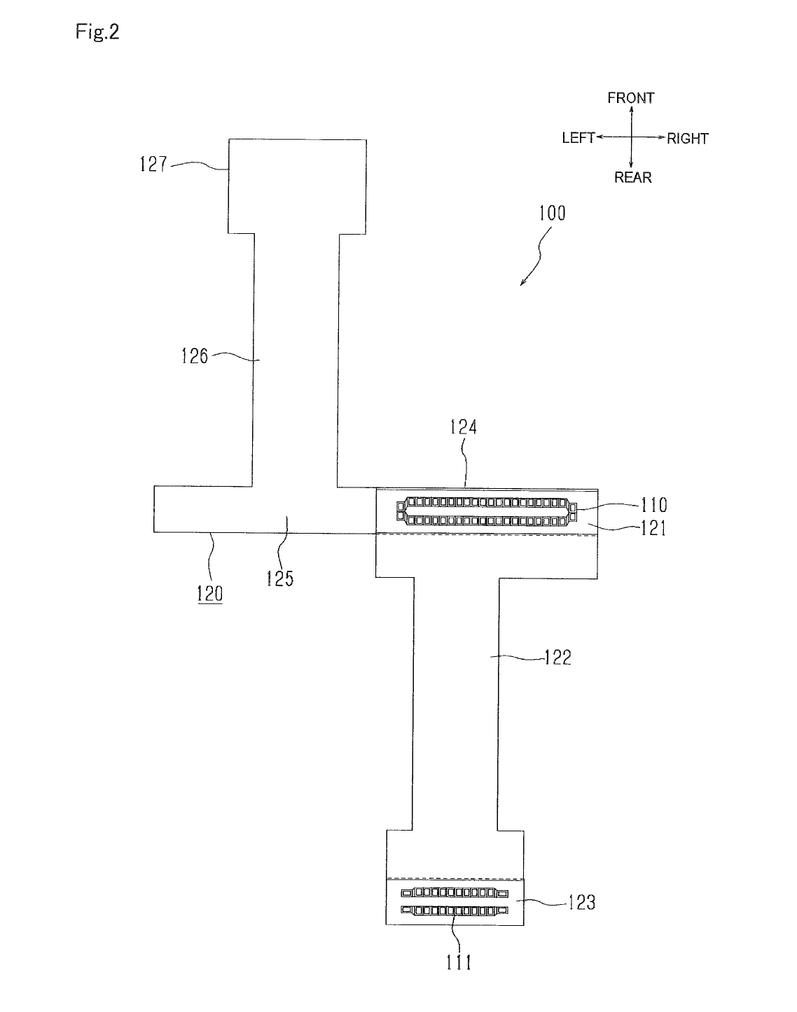

It is a plan view of a connector unit of an embodiment of the present invention, illustrating an initial condition without folding a flexible substrate.

[FIG. 2]

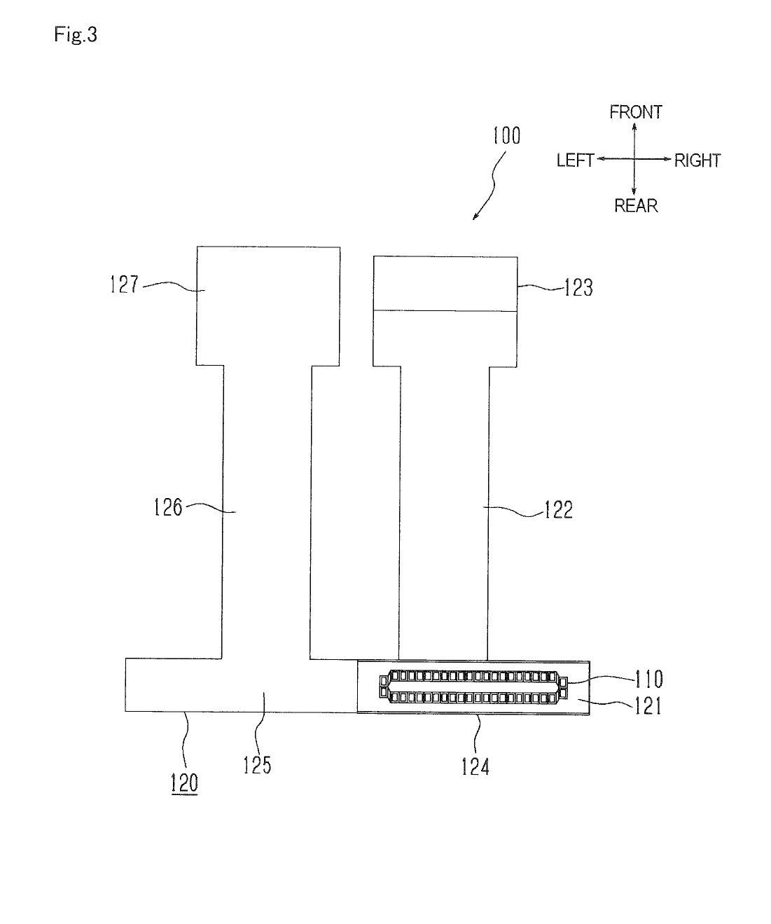

It is a plan view of the flexible substrate, illustrating a condition for forming a mountain fold in a boundary between a main installation section and a first connecting section.

[FIG. 3]

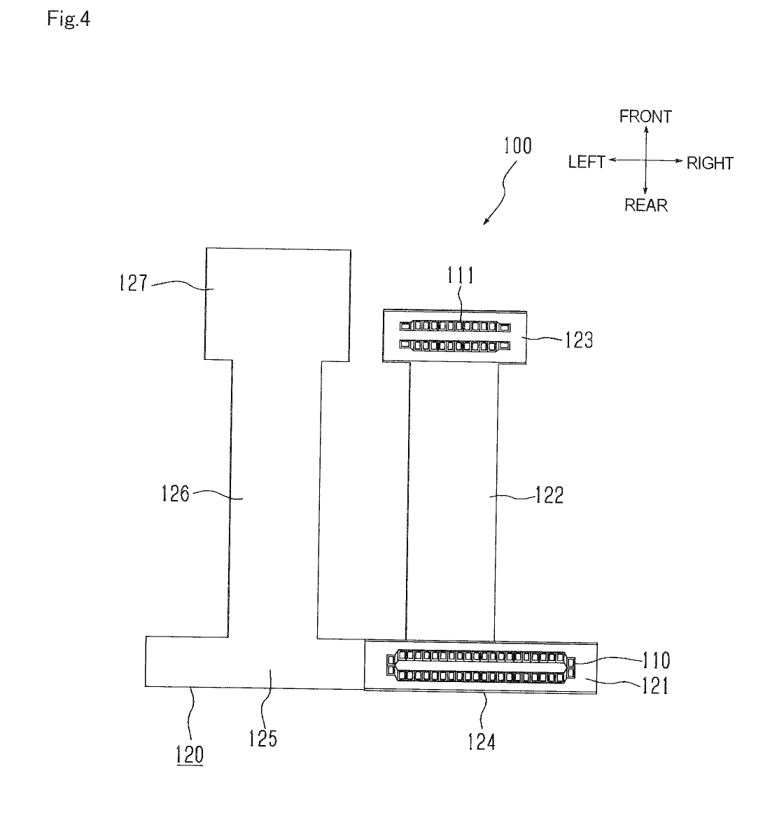

It is a plan view of the flexible substrate, illustrating a condition for forming a mountain fold in a boundary between a main installation section and a first elongated section.

[FIG. 4]

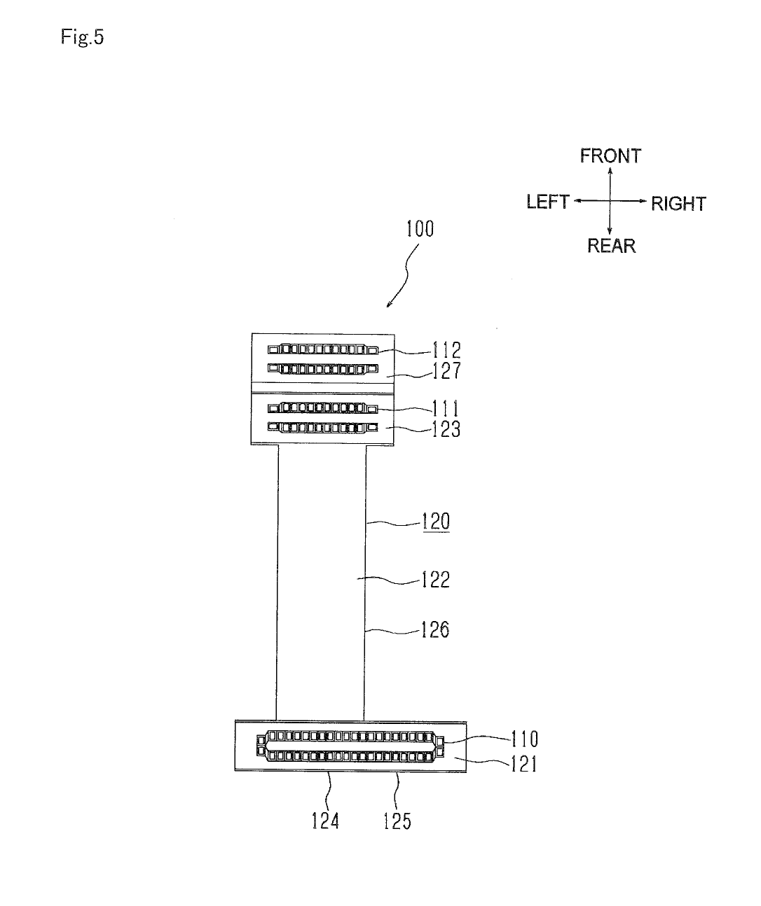

It is a plan view of a completion condition of a connector unit, illustrating a condition for forming a mountain fold in a boundary between a first elongated section and a first installation section.

[FIG. 5]

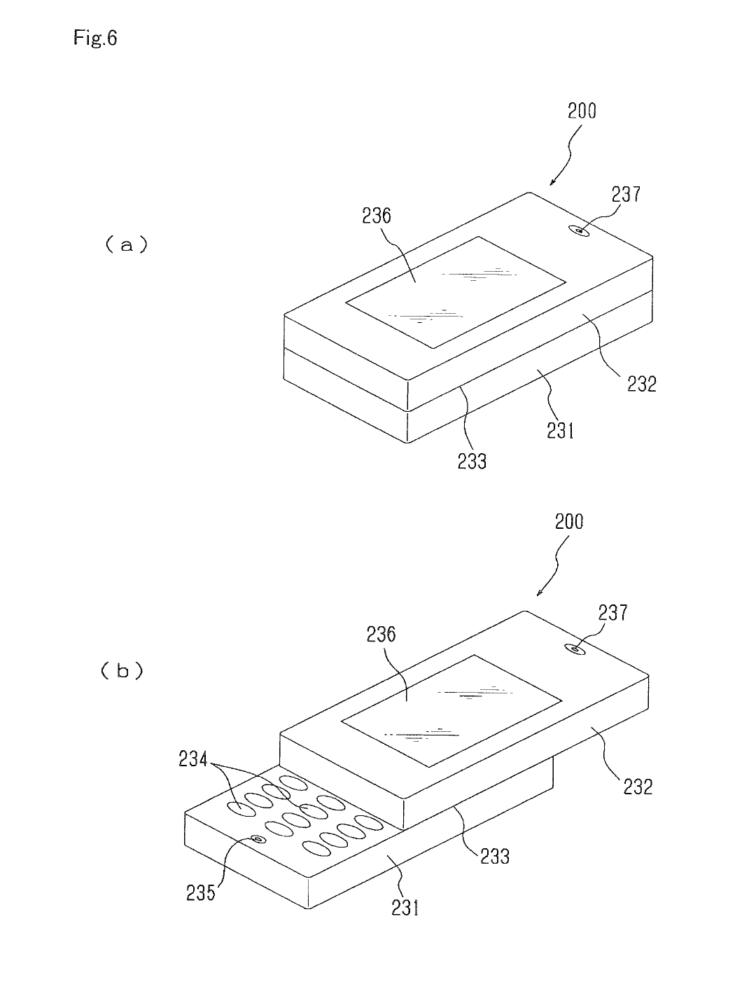

It is a plan view of the flexible substrate, illustrating a condition for forming a valley fold in a boundary between a first connecting section and a second elongated section.

[FIG. 6]

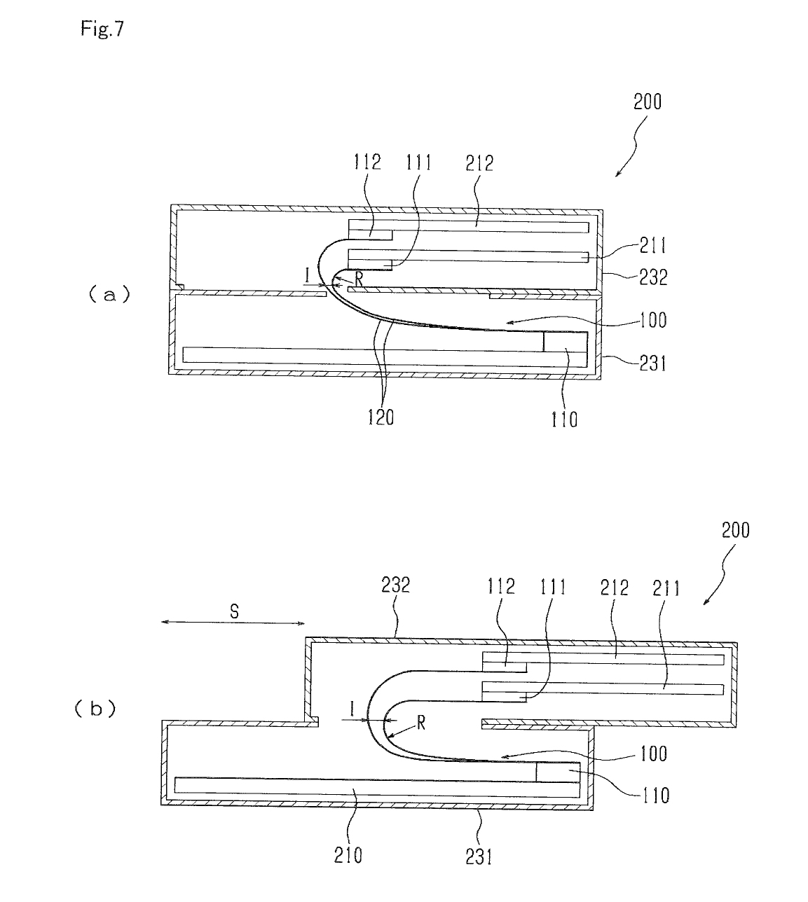

It is a perspective view, illustrating an outer appearance of electronic equipment.

[FIG. 7]

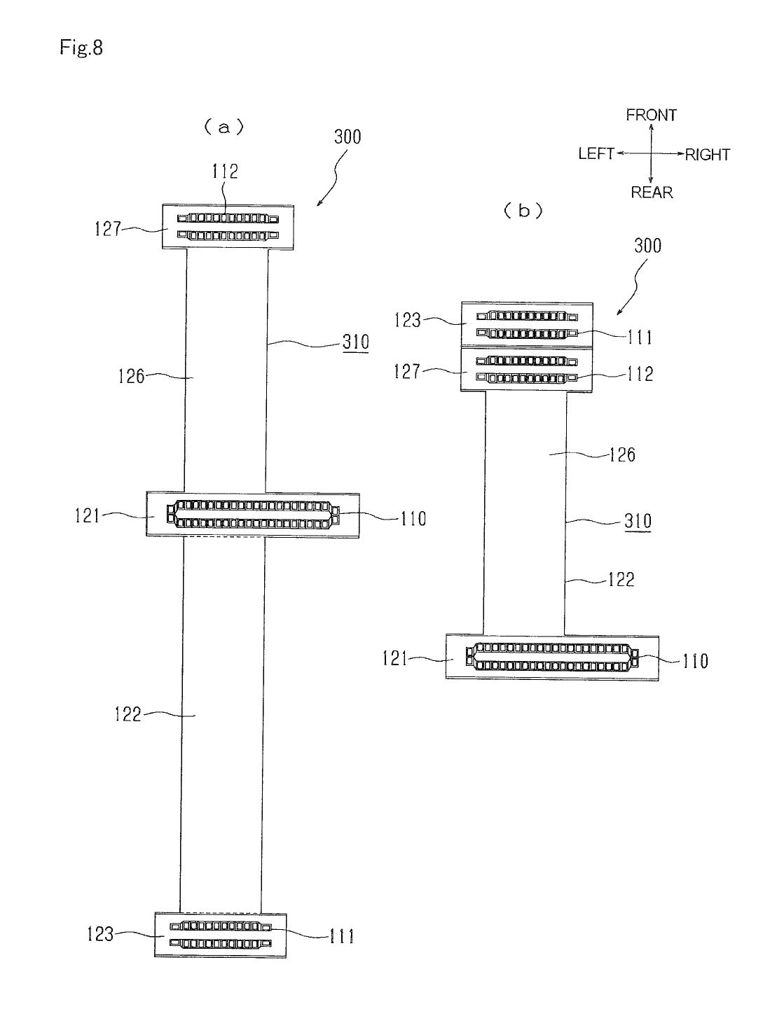

It is a schematic vertical side sectional view, illustrating an internal structure of electronic equipment.

[FIG. 8]

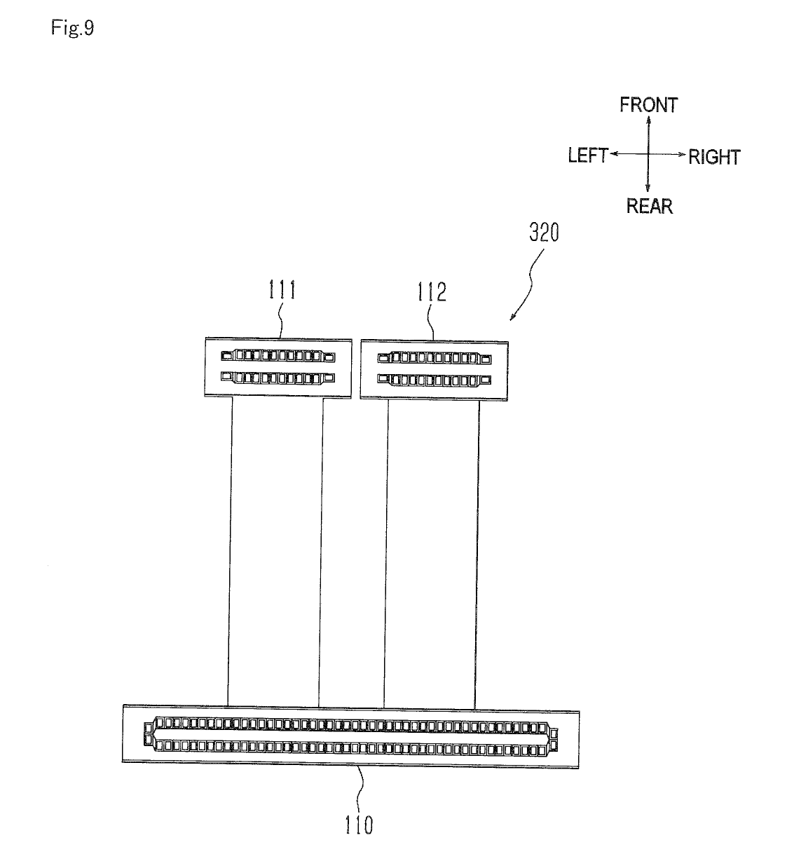

It is a plan view, illustrating a connector unit of an modified embodiment.

[FIG. 9]

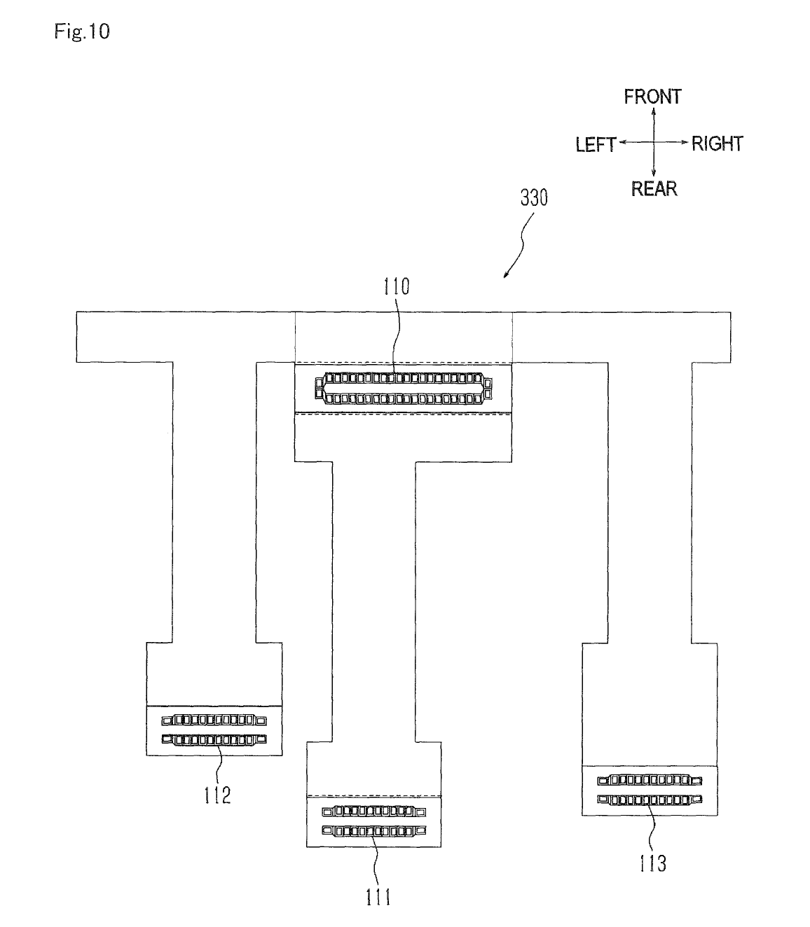

It is a plan view, illustrating a connector unit of another modified embodiment.

[FIG. 10]

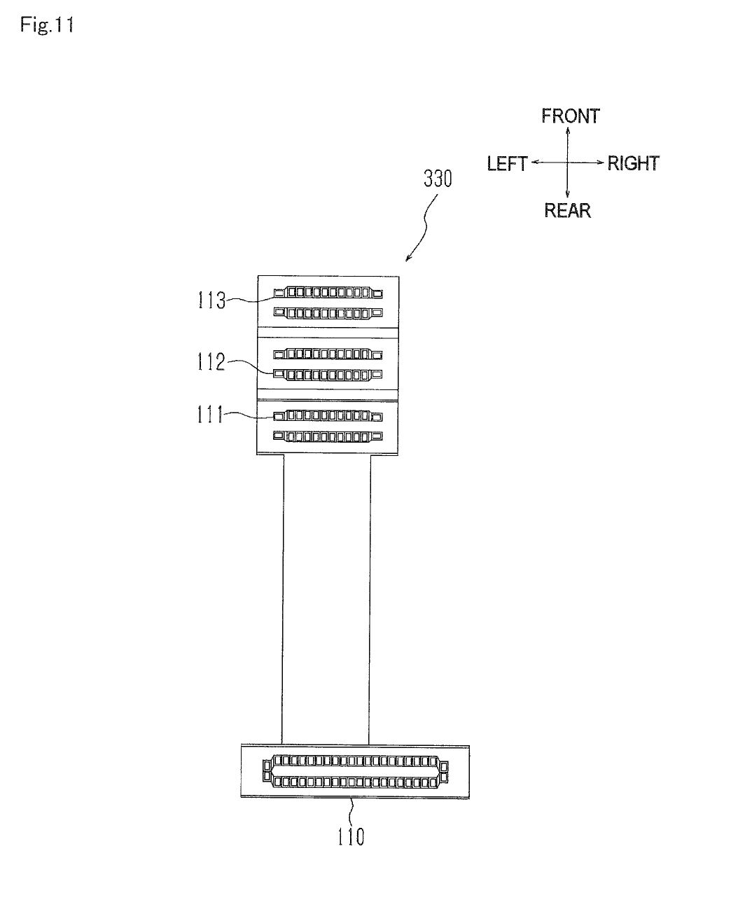

It is a plan view, illustrating a connector unit of yet other modified embodiment, illustrating an initial condition without folding a flexible substrate.

[FIG. 11]

It is a plan view, illustrating a connector unit in a completion condition.

### BEST MODE FOR CARRYING OUT THE INVENTION

A preferable embodiment of the present invention will be described below in reference to FIG. 1 to FIG. 7. Here, in the present embodiment, the descriptions will be made in reference to defined directions of front and rear, right and left, and top and bottom as shown. However, this definition is made for a convenience in providing simple description. Therefore, it is not intended to limit any directions for the manufacture or the use in case conducting the present invention.

A connector unit 100 of the present embodiment is, as shown in FIG. 1 to FIG. 5, the connector unit 100 configured to have a plurality of coupling connectors 110 to 112 installed in a flexible substrate 120.

The connector unit 100 includes: a main connector 110, which is one of the coupling connectors 110 to 112; a first sub-connector 111, which is one of the coupling connectors 110 to 112 and has smaller dimensional size than the main connector 110; a second sub-connector 112, which is one of the coupling connectors 110 to 112 and has smaller dimensional size than the first sub-connector 111; and a flexible substrate 120 provided with the main connector 110, the first sub-connector 111 and the second sub-connector 112, which are installed in one surface thereof.

The flexible substrate 120 has an elongated shape to provide an configuration that the main connector 110 is located in an end of one surface of the connector unit 100 and the first sub-connector 111 and the second sub-connector 112 are located in the other end when the flexible substrate 120 is folded at multiple locations.

In the electronic equipment 200 of the present embodiment, as shown in FIG. 6, circuit boards 210 to 212 are housed in each of the relatively slidable main housings 231 and 232. Further, a plurality of circuit boards 210 to 212 are coupled to trough the connector unit 100.

This electronic equipment 200 includes the first housing 231 which is one of the main housings, the second housing 232 which is one of the main housings, a sliding mechanism 233 supporting the first housing 231 and the second housing 232 in relatively slidable manner, the main substrate 210 which is a circuit board housed in the first housing 231, the first sub-substrate 211 which is one of the circuit boards housed in the second housing 232, the second sub-substrate 212 which is one of the circuit boards housed in the second housing 232 in parallel with the first sub-substrate 211, and the connector unit 100 that provides a connection of the main substrate 210 with the first sub-substrate 211 and the second sub-substrate 212.

More specifically, the flexible substrate 120 of the connector unit 100 according to the present embodiment includes, as shown in FIG. 1 and the like, a first elongated section 122 having an elongated shape and having a printed wiring (not shown) formed therein for connecting the main connector 110 with the first sub-connector 111, and a second elongated section 126 having an elongated shape and having a printed wiring (not shown) formed therein for connecting the main connector 110 with the second sub-connector 112.

Then, as shown in FIG. 5, the first elongated section 122 is overlapped over the second elongated section 126 by the folds in the flexible substrate 120. In this condition, the first sub-connector 111 and the second sub-connector 112 are arranged along an elongating direction of the folded flexible substrate 120.

The flexible substrate 120 of the connector unit 100 includes, as shown in FIG. 1, in a non-fold state of the flexible substrate 120: a main installation section 121 having the main connector 110 installed in an upper surface thereof; the first elongated section 122 abutted with a rear side of the main installation section 121; a first installation section 123 abutted with a rear side of the first elongated section 122 and having the first sub-connector 111 installed in an upper surface thereof; a first connecting section 124 abutted with a front side of the main installation section 121; a second connecting section 125 abutted with the left side of the first connecting section 124; the second elongated section 126 abutted with a rear side of the second connecting section 125; and a second installing section 127 abutted with a rear side of the second connecting section 125 and having the second sub-connector 112 installed in an upper surface thereof.

The flexible substrate 120 of the connector unit 100 includes, in a fold state: a mountain fold is made at a boundary of the main installation section 121 and the first connecting section 124; a mountain fold is made at a boundary of the main installation section 121 and the first elongated section 122; a valley fold is made at a boundary of the first connecting section 124 and the second elongated section 126; and a mountain fold is made at a boundary of the first elongated section 122 and the first installation section 123.

In addition, the electronic equipment 200 of the present embodiment is, for example, formed as so-called mobile telephone terminal. The electronic equipment 200 further includes, as shown in FIG. 6 and FIG. 7, the first housing 231, the second housing 232, and the sliding mechanism 233, which relatively slidably supports the first housing 231 and the second housing 232.

This sliding mechanism 233 has, for example, a configuration, in which guide rails formed in the upper section of the front surface of the first housing 231 and in the lower section of the rear surface of the second housing 232 are mutually slidably engaged, or the like (not shown).

As shown in FIG. 6, the first housing 231 is provided with a keyboard unit 234 and a microphone 235 installed in the lower section of the front surface thereof. The second housing 232 is provided with a display unit 236 and a speaker unit 237 installed in the front surface thereof.

The keyboard unit 234 and the microphone 235 are coupled to the main substrate 210. The display unit 236 and the speaker unit 237 are connected to at least one of the first sub-substrate 211 and the second sub-substrate 212.

As shown in FIG. 7, the main substrate 210 is housed in the first housing 231. The first sub-substrate 211 and the second sub-substrate 212 are housed in the second housing 232.

Openings are formed in the upper section of the front surface of the first housing 231 and in the lower section of the rear surface of the second housing 232, and the connector unit 100 is inserted through these openings.

The main substrate 210 is connected to the first sub-substrate 211 through the curved first elongated section 122. In addition, the main substrate 210 is connected to the second sub-substrate 212 through the second elongated section 126, which is curved and overlapped over the first elongated section 122.

As shown in FIG. 7, positions of the main connector 110, the first sub-connector 111 and the second sub-connector 112 and an overall length of the first elongated section 122 and the second elongated section 126 are defined, so that curved sections of the first elongated section 122 and the second elongated section 126 maintain a predetermined distance therebetween, even when a slide movement of the first housing 231 and the second housing 232 is caused.

In the electronic equipment 200 of the present embodiment, a distance I between the first elongated section 122 and the second elongated section 126 satisfies

0.1 mm≦I≦1 mm.

For example, the distance I is about 0.5 mm.

Further, a stroke S of a slide movement of the first housing 231 and the second housing 232 and a radius R of a presumed curvature of one of the first elongated section 122 and the second elongated section 126 located inside satisfy:

20 mm≦S≦50 mm; and

1 mm≦R≦3 mm.

More specifically, it satisfies:

1 mm≦R≦3 mm,

and for example, the stroke S is about 40 mm, and the radius R of the presumed curvature is about 2 mm.

Since a slide movement of the first housing 231 and the second housing 232 can be achieved in the electronic equipment 200 of the present embodiment in the configuration as described above, as shown in FIG. 6 and FIG. 7, both of the portability and the operability are achieved.

The main substrate 210 housed in the first housing 231 is connected to the first sub-substrate 211 housed in the second housing 232 and the second sub-substrate 212 through the connector unit 100 which is flexible.

Thus, a cable transmission of the main substrate 210 with the first sub-substrate 211 and the second sub-substrate 212 can be achieved without a trouble, when a slide movement of the first housing 231 and the second housing 232 is caused.

The connector unit 100 connecting the main substrate 210 with the first sub-substrate 211 and the second sub-substrate 212 provides no obstruction to the slide movement of the first housing 231 and the second housing 232.

Further, in the electronic equipment 200 of the present embodiment, the positions of the main connector 110, the first sub-connector 111 and the second sub-connector 112 and the overall length of the first elongated section 122 and the overall length of the second elongated section 126 are suitably adjusted.

Thus, the curved sections of the first elongated section 122 and the second elongated section 126 of the connector unit 100 maintain a predetermined distance therebetween, when a slide movement of the first housing 231 and the second housing 232 is caused. Therefore, no interference is occurred between the first elongated section 122 and the second elongated section 126 of the connector unit 100, even when a slide movement of the first housing 231 and the second housing 232 is caused.

Thus, in the electronic equipment 200 of the present embodiment, a generation of a disconnection in the first elongated section 122 or the second elongated section 126 is prevented, and drop-off of the connectors 110 to 112 from the substrates 210 to 212 is also prevented.

Moreover, in the connector unit 100 of the electronic equipment 200, the structure, in which one end of each of two flexible substrates is connected to a single main connector 110, and the other ends thereof are connected to the first sub-connector 111 and the second sub-connector 112, respectively, is formed of a single flexible substrate 120, which includes the main connector 110, the first sub-connector 111, and the second sub-connector 112 installed in one surface thereof. Thus, the connector unit 100 is special and yet easily manufacturable.

Here, the process for manufacturing the connector unit 100 of the present embodiment will be simply described hereinafter. First of all, as shown in FIG. 1, the flexible substrate 120 is formed to have a shape, which includes: the main installation section 121 having an upper surface allowing therein installing of the main connector 110; the first elongated section 122 abutted with the rear side of the main installation section 121; the first installation section 123 abutted with the rear side of the first elongated section 122 and having an upper surface allowing therein installing of the first sub-connector; the first connecting section 124 abutted with the front side of the main installation section 121; the second connecting section 125 abutted with one of the left side and the right side of the first connecting section 124; the second elongated section 126 abutted with the rear side of the second connecting section 125; and the second installation section 127 abutted with the rear side of the second connecting section 125 and having an upper surface allowing therein installing of the second sub-connector 112.

In the next, the main connector 110 is installed in the upper surface of the main installation section 121 of this flexible substrate 120, the first sub-connector 111 is installed in the upper surface of the first installation section 123, and the second sub-connector 112 is installed in the upper surface of the second installation section 127.

In the next, as shown in FIG. 2, a mountain fold is made at a boundary between the main installation section 121 and the first connecting section 124. As shown in FIG. 3, a mountain fold is made at a boundary between the main installation section 121 and the first elongated section 122.

As shown in FIG. 4, a mountain fold is made at a boundary with the first elongated section 122 and first installation section 123. As shown in FIG. 5, a valley fold is made at a boundary between the first connecting section 124 and the second elongated section 126. This provides the completion of the connector unit 100 of the present embodiment.

In the connector unit 100 of the present embodiment, the structure, in which one end of each of two flexible substrates is connected to a single main connector 110, and the other ends thereof are connected to the first sub-connector 111 and the second sub-connector 112, respectively, is formed of a single flexible substrate 120, which includes the main connector 110, the first sub-connector 111, and the second sub-connector 112 installed in one surface thereof. Thus, the structure, which is special and yet easily manufacturable, can be presented.

Further, in the electronic equipment 200 of the present embodiment as described above, the curved sections of the first elongated section 122 and the second elongated section 126 of the connector unit 100 maintain a predetermined distance therebetween, even when a slide movement of the first housing 231 and the second housing 232 is caused.

Thus, the slide movement of the first housing 231 and the second housing 232 does not cause an interference between the first elongated section 122 and the second elongated section 126 of the connector unit 100 to generate a disconnection, or does not cause a falling-off of the connectors 110 to 112 from the substrates 210 to 212.

The present invention is not limited to the present embodiment, and various modified versions may also be applicable without departing from the scope and the spirit of the invention. For example, the above-described embodiment assumes a mobile phone terminal for the electronic equipment 200.

Nevertheless, the present invention is also applicable for various types of electronic equipment including slidably configured first housing and second housing, and for example, is also applicable for a personal digital assistant (PDA), or a personal computer (not shown).

Further, the above-described embodiment illustrates that the second connecting section 125 is formed in the left side of the first connecting section 124 in the flexible substrate 120 of the connector unit 100. Alternatively, the second connecting section 125 may be formed in the right side of the first connecting section 124 (not shown).

In addition, while the above-described embodiment illustrates the flexible substrate 120 of the connector unit 100, in which the first connecting section 124 is abutted with the front side of the main installation section 121 having the main connector 110 installed therein, the second connecting section 125 is abutted with the left side of the first connecting section 124, and the second elongated section 126 and the second installing section 127 are abutted with the rear side of the second connecting section 125.

Alternatively, as in a connector unit 300 illustrated in FIG. 8, a flexible substrate 310 in the non-folded state may be linearly formed. More specifically, such flexible substrate 310 includes, as shown in FIG. 8(a), in non-fold state: the main installation section 121 having the main connector 110 installed in the upper surface thereof; the first elongated section 122 abutted with the rear side of the main installation section 121; a first installation section 123 abutted with the rear side of the first elongated section 122 and and having the first sub-connector 111 installed in an upper surface thereof; the second elongated section 126 abutted with the front side of the main installation section 121; and the second installation section 127 abutted with the front side of the second elongated section 126 and having the second sub-connector 112 installed in the upper surface thereof.

Then, in the fold state, a mountain fold is made at a boundary between the main installation section 121 and the first elongated section 122, and a mountain fold is made at a boundary between the first elongated section 122 and the first installation section 123.

In the connector unit 300, the structure, in which one end of each of two flexible substrates is connected to a single main connector 110, and the other ends thereof are connected to the first sub-connector 111 and the second sub-connector 112, respectively, is formed of a single flexible substrate 310, which includes the main connector 110, the first sub-connector 111, and the second sub-connector 112 installed in one surface thereof.

In addition to above, in the connector units 100 and 300, a larger number of coupling terminals of the connectors 110 to 112 are coupled in parallel by the printed wirings formed in the flexible substrates 120 and 310, However, in the connector units 100 and 300, the relation of the connection of the main connector and the second sub-connector by the printed wiring is bilaterally symmetric.

Further, the above-described embodiment illustrates that the first sub-connector 111 and the second sub-connector 112 are arranged along the elongating direction of the connector unit 100. Alternatively, as a connector unit 320 illustrated in FIG. 9, the first sub-connector 111 and the second sub-connector 112 may be arranged along a direction perpendicular to the elongating direction.

In addition, the above-described embodiment illustrates that the connector unit 100 includes the main connector 110, the first sub-connector 111 and the second sub-connector 112. Alternatively, as a connector unit 330 illustrated in FIG. 10 and FIG. 11, a third sub-connector 113 may be included.

1. A connector unit, configured to have a plurality of coupling connectors installed in a flexible substrate, comprising:
a main connector, which is included in said coupling connectors;
a first sub-connector, which is included in said coupling connectors and has a smaller dimension than said main connector;
a second sub-connector, which is included in said coupling connectors and has a smaller dimension than said main connector; and
a flexible substrate having said main connector, said first sub-connector and said second sub-connector, which are installed in one surface of said flexible substrate,
wherein said flexible substrate having an elongated shape to provide an configuration that said main connector is located in an end of one surface of said connector unit and said first sub-connector and said second sub-connector are located in the other end when said flexible substrate is folded at multiple locations.

2. The connector unit according to claim 1, wherein said first sub-connector and said second sub-connector are arranged along an elongating direction of said folded flexible substrate.

3. The connector unit according to claim 1,
wherein said flexible substrate includes a first elongated section having an elongated shape and having a printed wiring formed therein for connecting said main connector with said first sub-connector, and a second elongated section having an elongated shape and having a printed wiring formed therein for connecting said main connector with said second sub-connector, and
wherein said first elongated section is overlapped over said second elongated section in a folded state of said flexible substrate.

4. The connector unit according to claim 3,
wherein said flexible substrate includes, in a non-folded state of said flexible substrate: a main installation section having said main connector installed in an upper surface; said first elongated section abutted with a rear side of said main installation section; a first installation section abutted with a rear side of said first elongated section and having said first sub-connector installed in an upper surface; a first connecting section abutted with a front side of said main installation section; a second connecting section abutted with one of right side and left side of said first connecting section; said second elongated section abutted with a rear side of said second connecting section; and a second installation section abutted with a rear side of said second connecting section and having said second sub-connector installed in an upper surface, and
wherein said flexible substrate is configured, in said folded state: a mountain fold is made at a boundary of said main installation section and said first connecting section; a mountain fold is made at a boundary of said main installation section and said first elongated section; a valley fold is made at a boundary of said first connecting section and said second elongated section; and a mountain fold is made at a boundary of said first elongated section and said first installation section.

5. The connector unit according to claim 3,
wherein said flexible substrate includes, in a non-folded state of said flexible substrate: a main installation section having said main connector installed in an upper surface; said first elongated section abutted with a rear side of said main installation section; a first installation section abutted with a rear side of said first elongated section and having said first sub-connector installed in an upper surface; said second elongated section abutted with a front side of said main installation section; and a second installation section abutted with a front side of said second elongated section and having said second sub-connector installed in an upper surface, and
wherein said flexible substrate is configured, in said folded state: a mountain fold is made at a boundary of said main installation section and said first elongated section; and a mountain fold is made at a boundary of said first elongated section and said first installation section.

6. Electronic equipment, configured to have a plurality of circuit boards coupled via a connector unit, comprising:
said connector unit, configured to have a plurality of coupling connectors installed in a flexible substrate, comprising:
a main connector, which is included in said coupling connectors;
a first sub-connector, which is included in said coupling connectors and has a smaller dimension than said main connector;
a second sub-connector, which is included in said coupling connectors and has a smaller dimension than said main connector; and
a flexible substrate having said main connector, said first sub-connector and said second sub-connector, which are installed in one surface of said flexible substrate,
wherein said flexible substrate having an elongated shape to provide an configuration that said main connector is located in an end of one surface of said connector unit and said first sub-connector and said second sub-connector are located in the other end when said flexible substrate is folded at multiple locations;
a main substrate, included in said circuit boards and coupled with a main connector of said connector unit;
a first sub-substrate, included in said circuit boards and coupled with a first sub-connector of said connector unit; and
a second sub-substrate, included in said circuit boards and coupled with a second sub-connector of said connector unit.

7. The electronic equipment according to claim 6, further comprising: a first housing, a second housing, and a sliding mechanism relatively-slidably supporting said first housing and said second housing,
wherein said main substrate is housed in said first housing, and said first sub-substrate and said second sub-substrate are housed in said second housing.

8. The electronic equipment according to claim 7,
wherein said flexible substrate includes a first elongated section having an elongated shape and having a printed wiring formed therein for connecting said main connector with said first sub-connector, and a second elongated section having an elongated shape and having a printed wiring formed therein for connecting said main connector with said second sub-connector,
wherein said first said elongated section is overlapped over said second elongated section in a folded state of said flexible substrate,
wherein said main substrate is coupled with said first sub-substrate via said first elongated section having a curved feature, and
wherein said main substrate is coupled with said second sub-substrate via said second elongated section having a curved feature to be overlapped over said first elongated section.

9. The electronic equipment according to claim 8,
wherein positions of said main connector, said first sub-connector and said second sub-connector and an overall length of said first elongated section and said second elongated section are defined, so that curved sections of said first elongated section and said second elongated section maintain a predetermined distance therebetween, even when a slide movement of said first housing and said second housing is made.

10. The electronic equipment according to claim 9,
wherein a distance I between said first elongated section and said second elongated section satisfies:
0.1 mm≦I≦1 mm.

11. The electronic equipment according to claim 10,
wherein a stroke S of said slide movement of said first housing and said second housing and a radius R of a presumed curvature of one of said first elongated section and said second elongated section located inside satisfy:
20 mm≦S≦50 mm and
0.5 mm≦R≦10 mm.

12. The electronic equipment according to claim 11,
wherein said radius R of said presumed curvature satisfies:
1 mm≦R≦3 mm.

13. A flexible substrate comprising:
a main installation section having an upper surface allowing therein installing of a main connector which is included in a plurality of coupling connectors;
a first elongated section having an elongated shape and abutted with a rear side of said main installation section;
a first installation section abutted with a rear side of said first elongated section and having an upper surface allowing therein installing of a first sub-connector which is included in said coupling connectors and has a smaller dimension than said main connector;
a first connecting section abutted with a front side of said main installation section;
a second connecting section abutted with one of right side and left side of said first connecting section;
a second elongated section having an elongated shape and abutted with a rear side of said second connecting section; and
a second installation section abutted with a rear side of said second connecting section and having an upper surface allowing therein installing of a second sub-connector which is included in said coupling connectors and has a smaller dimension than said main connector,
wherein said first elongated section has a printed wiring formed therein for connecting said main connector with said first sub-connector,
wherein said second elongated section has a printed wiring formed therein for connecting said main connector with said second sub-connector,
wherein said first elongated section is overlapped over said second elongated section; said main connector is located in an end of one surface of said flexible substrate and said first sub-connector and said second sub-connector are located in the other end; and said first sub-connector and said second sub-connector are arranged along an elongating direction of said flexible substrate, when a mountain fold is made at a boundary of said main installation section and said first connecting section; a mountain fold is made at a boundary of said main installation section and said first elongated section; a valley fold is made at a boundary of said first connecting section and said second elongated section; and a mountain fold is made at a boundary of said first elongated section and said first installation section.

14. A flexible substrate comprising:
a main installation section having an upper surface allowing therein installing of a said main connector which is included in a plurality of coupling connectors;
a first elongated section having an elongated shape and abutted with a rear side of said main installation section;
a first installation section abutted with a rear side of said first elongated section and having an upper surface allowing therein installing of a first sub-connector which is included in said coupling connectors and has a smaller dimension than said main connector;
a second elongated section having an elongated shape and abutted with a front side of said main installation section; and
a second installation section abutted with a front side of said second elongated section and having an upper surface allowing therein installing of a second sub-connector which is included in said coupling connectors and has a smaller dimension than said main connector,
wherein said first elongated section has a printed wiring formed therein for connecting said main connector with said first sub-connector,
wherein said second elongated section has a printed wiring formed therein for connecting said main connector with said second sub-connector,
wherein said first elongated section is overlapped over said second elongated section; said main connector is located in an end of one surface of said flexible substrate and said first sub-connector and said second sub-connector are located in the other end; and said first sub-connector and said second sub-connector are arranged along an elongating direction of said flexible substrate, when a mountain fold is made at a boundary of said main installation section and said first elongated section; and a mountain fold is made at a boundary of said first elongated section and said first installation section.

15. A process for manufacturing the connector unit including:
forming a flexible substrate, said flexible substrate comprising: a main installation section having an upper surface allowing therein installing of a main connector which is included in a plurality of coupling connectors; a first elongated section having an elongated shape and abutted with a rear side of said main installation section; a first installation section abutted with a rear side of said first elongated section and having an upper surface allowing therein installing of a first sub-connector which is included in said coupling connectors and has a smaller dimension than said main connector; a first connecting section abutted with a front side of said main installation section; a second connecting section abutted with one of right side and left side of said first connecting section; a second elongated section having an elongated shape and abutted with a rear side of said second connecting section; and a second installation section abutted with a rear side of said second connecting section and having an upper surface allowing therein installing of a second sub-connector which is included in said coupling connectors and has a smaller dimension than said main connector; wherein said first elongated section having a printed wiring formed therein for connecting said main connector with said first sub-connector; wherein said second elongated section having a printed wiring formed therein for connecting said main connector with said second sub-connector;
installing said main connector in said upper surface of said main installation section;
installing said first sub-connector in said upper surface of said first installation section;
installing said second sub-connector in said upper surface of said second installation section;
wherein said first elongated section is overlapped over said second elongated section; said main connector is located in an end of one surface of said connector unit and said first sub-connector and said second sub-connector are located in the other end; and said first sub-connector and said second sub-connector are arranged along an elongating direction of said flexible substrate, through a folding step;
wherein said folding step, make a mountain fold at a boundary of said main installation section and said first connecting section; make a mountain fold at a boundary of said main installation section and said first elongated section; make a valley fold at a boundary of said first connecting section and said second elongated section; and make a mountain fold at a boundary of said first elongated section and said first installation section.

16. A process for manufacturing the connector unit including:
Forming a flexible substrate, said flexible substrate comprising: a main installation section having an upper surface allowing therein installing of a main connector which is included in a plurality of coupling connectors; a first elongated section having an elongated shape and abutted with a rear side of said main installation section; a first installation section abutted with a rear side of said first elongated section and having an upper surface allowing therein installing of a first sub-connector which is included in said coupling connectors and has a smaller dimension than said main connector; a second elongated section having an elongated shape and abutted with a front side of said main installation section; and a second installation section abutted with a front side of said second elongated section and having an upper surface allowing therein installing of a second sub-connector which is included in said coupling connectors and has a smaller dimension than said main connector; wherein said first elongated section having a printed wiring formed therein for connecting said main connector with said first sub-connector; wherein said second elongated section having a printed wiring formed therein for connecting said main connector with said second sub-connector;
installing said main connector in said upper surface of said main installation section;
installing said first sub-connector in said upper surface of said first installation section;
installing said second sub-connector in said upper surface of said second installation section;
wherein said first elongated section is overlapped over said second elongated section; said main connector is located in an end of one surface of said flexible substrate and said first sub-connector and said second sub-connector are located in the other end; and said first sub-connector and said second sub-connector are arranged along an elongating direction of said flexible substrate, through a folding step;
wherein said folding step, make a mountain fold at a boundary of said main installation section and said first elongated section; and make a mountain fold at a boundary of said first elongated section and said first installation section.

17. An electronic equipment, configured to have relatively slidable plurality of main housings, each of which contains a circuit board housed therein, comprising:
a first housing, included in said main housings;
a second housing, included in said main housings;
a sliding mechanism, relatively slidably supporting said first housing and said second housing;
a main substrate serving as said circuit board housed in said first housing;
a first sub-substrate serving as said circuit board housed in said second housing;
a second sub-substrate serving as said circuit board housed in said second housing in parallel with said first sub-substrate; and
a connector unit, connecting said main substrate with said first sub-substrate and said second sub-substrate,
wherein said connector unit comprises:
a main connector serving as a coupling connector coupled to said main substrate;
a first sub-connector serving as a coupling connector coupled to said first sub-substrate;
a second sub-connector serving as a coupling connector coupled to said second sub-substrate;
a first elongated section composed of a flexible substrate and coupling said main connector with said first sub-connector; and
a second elongated section composed of a flexible substrate and coupling said main connector with said second sub-connector,
wherein said main substrate is coupled with said first sub-substrate via said first elongated section having a curved feature,
wherein said main substrate is coupled with said second sub-substrate via said second elongated section having a curved feature to be overlapped over said first elongated section, and
wherein positions of said main connector, said first sub-connector and said second sub-connector and an overall length of said first elongated section and said second elongated section are defined, so that curved sections of said first elongated section and said second elongated section maintain a predetermined distance therebetween, even when a slide movement of said first housing and said second housing is made.

18. The electronic equipment according to claim 17,
wherein a distance I between said first elongated section and said second elongated section satisfies:
0.1 mm≦I≦1 mm.

19. The electronic equipment according to claim 18,
wherein a stroke S of said slide movement of said first housing and said second housing and a radius R of a presumed curvature of one of said first elongated section and said second elongated section located inside satisfy:
20 mm≦S≦50 mm and
0.5 mm≦R≦10 mm.

20. The electronic equipment according to claim 19,
wherein said radius R of said presumed curvature satisfies:
1 mm≦R≦3 mm.

21. The electronic equipment according to claim 17, further comprising:
a keyboard unit coupled to said main substrate and disposed in a surface of said first housing; and
a display unit coupled to at least one of said first sub-substrate and said second sub-substrate and disposed in a surface of said second housing.

22. The electronic equipment according to claim 17 composed of a mobile telephone terminal, further comprising:
a microphone coupled to said main substrate and installed in said first housing; and
a speaker unit coupled to at least one of said first sub-substrate and said second sub-substrate and installed in said second housing.

23. The electronic equipment according to claim 17,
wherein said connector unit includes a flexible substrate having said main connector, said first sub-connector and said second sub-connector, which are installed in one surface thereof, and
wherein said flexible substrate having an elongated shape to provide an configuration that said main connector is located in an end of one surface of said connector unit and said first sub-connector and said second sub-connector are located in the other end when said flexible substrate is folded at multiple locations.

24. The electronic equipment according to claim 23,
wherein said flexible substrate includes, in a non-folded state of said flexible substrate: a main installation section having said main connector installed in an upper surface; said first elongated section abutted with a rear side of said main installation section; a first installation section abutted with a rear side of said first elongated section and having said first sub-connector installed in an upper surface; a first connecting section abutted with a front side of said main installation section; a second connecting section abutted with one of right side and left side of said first connecting section; said second elongated section abutted with a rear side of said second connecting section; and a second installation section abutted with a rear side of said second connecting section and having said second sub-connector installed in an upper surface, and
wherein said flexible substrate is configured, in a fold state of said flexible substrate: a mountain fold is made at a boundary of said main installation section and said first connecting section; a mountain fold is made at a boundary of said main installation section and said first elongated section; a valley fold is made at a boundary of said first connecting section and said second elongated section; and a mountain fold is made at a boundary of said first elongated section and said first installation section.

25. The electronic equipment according to claim 23,
wherein said flexible substrate includes, in a non-folded state of said flexible substrate: a main installation section having said main connector installed in an upper surface; said first elongated section abutted with a rear side of said main installation section; a first installation section abutted with a rear side of said first elongated section and having said first sub-connector installed in an upper surface; said second elongated section abutted with a front side of said main installation section; and a second installation section abutted with a front side of said second elongated section and having said second sub-connector installed in an upper surface, and
wherein said flexible substrate is configured, in a fold state of said flexible substrate: a mountain fold is made at a boundary of said main installation section and said first elongated section; and a mountain fold is made at a boundary of said first elongated section and said first installation section.
